(19) United States
(12) Patent Application Publication
(10) Pub. No.: US 2026/0136874 A1
(43) Pub. Date: May 14, 2026

(54) MOUNTING APPARATUS, MOUNTING METHOD, AND NON-TRANSITORY COMPUTER-READABLE RECORDING MEDIUM

(71) Applicant: SHINKAWA LTD., Tokyo (JP)

(72) Inventors: Kohei Seyama, Tokyo (JP); Akira Sekikawa, Tokyo (JP)

(73) Assignee: SHINKAWA LTD., Tokyo (JP)

(21) Appl. No.: 19/121,789

(22) PCT Filed: Aug. 18, 2023
(86) PCT No.: PCT/JP2023/029799

§ 371 Date: Apr. 16, 2025

(30) Foreign Application Priority Data
Nov. 16, 2022 (JP) 2022-183647

(51) Int. Cl. H10P 72/00; G06T 7/80

(52) U.S. Cl. CPC H10P 72/0446; G06T 7/80; H10P 72/0606

(57) ABSTRACT

In a mounting apparatus, a head part supports: a first imaging unit and a second imaging unit each including an optical system and an imaging element disposed to satisfy a Scheimpflug condition such that a plane parallel to a reference plane becomes a focal plane; and a mounting tool performing a mounting work. The mounting apparatus includes a detection part detecting an inclination of a stage surface or a work plane with respect to the reference plane using height information of each of multiple spots calculated based on a first top-view image and a second top-view image obtained by displacing the head part with respect to a stage and causing the first imaging unit and the second imaging unit to respectively capture and output images of the multiple spots of the stage surface or the work plane serving as a target of the mounting processing.

### TECHNICAL FIELD

The present invention relates to a mounting apparatus, a mounting method, and a mounting control program.

### RELATED ART

In a mounting apparatus mounting a semiconductor chip onto a substrate, maintaining the substrate, which is a mounting target, to be parallel to a reference plane is important for precisely mounting the semiconductor chip to a target position. For example, in a TCB method performed up to joining of a solder joining part during mounting, maintaining a joining surface to be horizontal significantly affects control of a solder gap. Not limited to a mounting apparatus of semiconductor chips, horizontal adjustment of a stage is important in semiconductor processing apparatuses in general, and techniques of, for example, irradiating laser light onto the stage to perform horizontal adjustment have become widespread (e.g., refer to Patent Document 1).

### RELATED ART DOCUMENTS

### Patent Documents

Patent Document 1: Japanese Patent Application Laid-Open No. 2000-114141

### SUMMARY OF INVENTION

### Problem to Be Solved by Invention

A laser light irradiation unit is provided specially for horizontal adjustment of the stage, which complicates the apparatus configuration. In addition, the horizontal adjustment of the stage using the laser light irradiation unit is implemented separately from the mounting processing of mounting the semiconductor chip onto the substrate, which also becomes a cause of reduced work efficiency.

The present invention has been made to solve such problems and provides a mounting apparatus and the like capable of detecting an inclination of a stage surface or a work plane serving as a target of a mounting work without adding a dedicated detection unit, and capable of improving work efficiency of a mounting processing.

### Means for Solving Problem

A mounting apparatus of a first aspect of the present invention includes a stage, a mounting tool, a first imaging unit and a second imaging unit, a head part, and a detection part. A substrate to be mounted with a mounting body is placed on the stage. The mounting tool performs a mounting work on at least one of the substrate placed on the stage and another mounting body already mounted on the substrate. The first imaging unit and the second imaging unit each include an optical system and an imaging element disposed to satisfy a Scheimpflug condition such that a plane parallel to a reference plane becomes a focal plane, and serve to capture, in a top view, images of a work area in which the mounting work is performed. The head part supports the mounting tool, the first imaging unit, and the second imaging unit and is displaceable with respect to the stage. The detection part detects an inclination of a stage surface of the stage or a work plane including the work area with respect to the reference plane using height information of each of multiple spots calculated based on a first top-view image and a second top-view image obtained by displacing the head part and causing the first imaging unit and the second imaging unit to respectively capture and output images of the multiple spots of the stage surface or the work plane.

In addition, a mounting method of a second aspect of the present invention is a mounting method of a mounting body using a mounting apparatus. The mounting apparatus includes a stage, a mounting tool, a first imaging unit and a second imaging unit, and a head part. A substrate to be mounted with the mounting body is placed on the stage. The mounting tool performs a mounting work on at least one of the substrate placed on the stage and another mounting body already mounted on the substrate. The first imaging unit and the second imaging unit each include an optical system and an imaging element disposed to satisfy a Scheimpflug condition such that a plane parallel to a reference plane becomes a focal plane, and serve to capture, in a top view, images of a work area in which the mounting work is performed. The head part supports the mounting tool, the first imaging unit, and the second imaging unit and is displaceable with respect to the stage. The mounting method includes: an acquisition step of acquiring height information of each of multiple spots calculated based on a first top-view image and a second top-view image obtained by displacing the head part and causing the first imaging unit and the second imaging unit to respectively capture and output images of the multiple spots of a stage surface of the stage or a work plane including the work area; and a detection step of detecting an inclination of the stage surface or the work plane with respect to the reference plane using the height information.

In addition, a mounting control program of a third aspect of the present invention is a mounting control program controlling a mounting apparatus. The mounting apparatus includes a stage, a mounting tool, a first imaging unit and a second imaging unit, and a head part. A substrate to be mounted with a mounting body is placed on the stage. The mounting tool performs a mounting work on at least one of the substrate placed on the stage and another mounting body already mounted on the substrate. The first imaging unit and the second imaging unit each include an optical system and an imaging element disposed to satisfy a Scheimpflug condition such that a plane parallel to a reference plane becomes a focal plane, and serve to capture, in a top view, images of a work area in which the mounting work is performed. The head part supports the mounting tool, the first imaging unit, and the second imaging unit and is displaceable with respect to the stage. The mounting control program causes a computer to execute: an acquisition step of acquiring height information of each of multiple spots calculated based on a first top-view image and a second top-view image obtained by displacing the head part and causing the first imaging unit and the second imaging unit to respectively capture and output images of the multiple spots of a stage surface of the stage or a work plane including the work area; and a detection step of detecting an inclination of the stage surface or the work plane with respect to the reference plane using the height information.

### Effects of Invention

The present invention can provide a mounting apparatus and the like capable of detecting an inclination of a stage surface or a work plane serving as a target of a mounting work without adding a dedicated detection unit, and capable of improving work efficiency of a mounting processing.

### BRIEF DESCRIPTION OF THE DRAWINGS

FIG. 1 is an overall configuration view of a flip chip bonder including a bonding apparatus according to the present embodiment.

FIG. 2 is a system configuration diagram of the bonding apparatus.

FIG. 3 is a view for illustrating a Scheimpflug optical system.

FIG. 4 is a view showing three imaging units capturing images of a calibration index.

FIG. 5 is a view showing a bonding tool picking up a semiconductor chip.

FIG. 6 is a view showing a third imaging unit capturing an image of the semiconductor chip.

FIG. 7 is a view schematically showing a bottom-view image outputted by the third imaging unit.

FIG. 8 is a view showing a first imaging unit and a second imaging unit capturing images of a lead frame.

FIG. 9 is a partial perspective view of FIG. 8.

FIG. 10 is a view showing a procedure up to calculating target coordinates for placing the semiconductor chip from a first top-view image and a second top-view image.

FIG. 11 is a view showing the bonding tool placing and bonding the semiconductor chip to a target position.

FIG. 12 is a view showing the bonding tool retracting.

FIG. 13 is a view illustrating a detection principle for detecting an inclination of a frame surface with respect to a reference plane.

FIG. 14 is a view showing performing parallel adjustment of the frame surface.

FIG. 15 is a flowchart illustrating a bonding procedure of the semiconductor chip.

FIG. 16 is a sub-flowchart illustrating a procedure of a calibration control step.

FIG. 17 is a sub-flowchart illustrating a procedure of a mounting control step.

FIG. 18 is a sub-flowchart illustrating a procedure of a parallel adjustment step.

FIG. 19 is a partial perspective view of a flip chip bonder for illustrating a first application example.

FIG. 20 is a partial perspective view of a wire bonder for illustrating a second application example.

### EMBODIMENTS FOR IMPLEMENTING INVENTION

Hereinafter, the present invention will be described based on embodiments of the invention, but the invention related to the claims is not limited to the following embodiments. In addition, not all configurations described in the embodiments are necessarily essential as means for solving the problems. In each figure, in the case where multiple structures having the same or similar configurations are present, to avoid complexity, reference signs may be labeled on a part of them, and labeling of the same reference signs may be omitted on the rest.

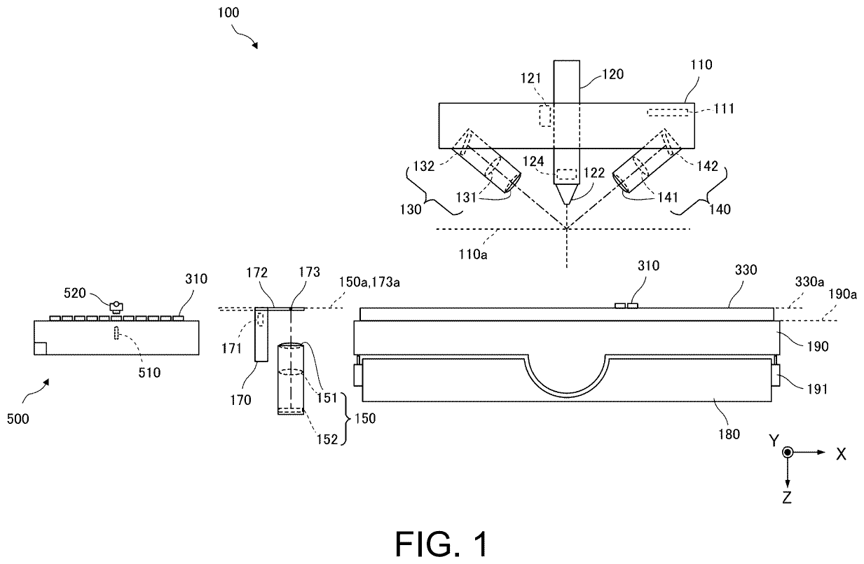

FIG. 1 is an overall configuration view of a flip chip bonder including a bonding apparatus 100 according to the present embodiment. The flip chip bonder is mainly composed of the bonding apparatus 100 as an example of a mounting apparatus and a chip feeding apparatus 500. The chip feeding apparatus 500 is an apparatus that places a diced semiconductor chip 310, which serves as a mounting body, on an upper surface thereof to feed to the bonding apparatus 100. Specifically, the chip feeding apparatus 500 includes a pickup mechanism 510 and an inversion mechanism 520. The pickup mechanism 510 is an apparatus that pushes up any of the placed semiconductor chips 310 toward the inversion mechanism 520. The inversion mechanism 520 is an apparatus that adsorbs and inverts the semiconductor chip 310 pushed up by the pickup mechanism 510 to thus reverse an orientation thereof in an up-down direction. The bonding apparatus 100 is an apparatus that picks up, by a bonding tool 120 (to be described later), the semiconductor chip 310 adsorbed in a state inverted by the inversion mechanism 520, and places and adheres the semiconductor chip 310 to a target position of a lead frame 330. The lead frame 330 is an example of a substrate placed on a stage 190.

The bonding apparatus 100 mainly includes a head part 110, a bonding tool 120, a first imaging unit 130, a second imaging unit 140, a third imaging unit 150, a calibration unit 170, and a stage 190. The head part 110 supports the bonding tool 120, the first imaging unit 130, and the second imaging unit 140, and is movable in a plane direction and a perpendicular direction by a head drive motor 111. In other words, the head part 110 is displaceable with respect to the stage 190. In the present embodiment, the plane direction is a horizontal direction defined by an X-axis direction and a Y-axis direction as shown in the figure, and the perpendicular direction (height direction) is a Z-axis direction orthogonal to the X-axis direction and the Y-axis direction.

The bonding tool 120 is movable in the height direction with respect to the head part 110 by a tool drive motor 121. The bonding tool 120 is an example of a mounting tool and has a collet 122 adsorbing the semiconductor chip 310 at a tip, and a heater 124 heating the semiconductor chip 310 adsorbed by the collet 122. The bonding tool 120 places the semiconductor chip 310 adsorbed by the collet 122 to a predetermined position set on a frame surface 330a of the lead frame 330 placed on the stage 190, and heats the semiconductor chip 310 by the heater 124 while pressing by the tip of the collet 122 to adhere the semiconductor chip 310.

The first imaging unit 130 and the second imaging unit 140 are imaging units that capture images of the lead frame 330 in a top view. The first imaging unit 130 includes a first optical system 131 and a first imaging element 132, and is obliquely provided at the head part 110 with an optical axis thereof oriented toward below the bonding tool 120. The first optical system 131 and the first imaging element 132 are disposed to satisfy the Scheimpflug condition such that a plane parallel to a reference plane becomes a focal plane 110a. In the present embodiment, the reference plane is a horizontal plane. Which plane is taken as the reference plane is determined according to properties of the mounting apparatus and usage status thereof.

The second imaging unit 140 includes a second optical system 141 and a second imaging element 142, and is obliquely provided at the head part 110 on a side opposite to the first imaging unit 130 with respect to the bonding tool 120, with an optical axis thereof oriented toward below the bonding tool 120. The second optical system 141 and the second imaging element 142 are disposed to satisfy the Scheimpflug condition such that a plane parallel to the reference plane becomes the focal plane 110a, similar to the first optical system 131 and the first imaging element 132. In the following description, the first imaging unit 130 and the second imaging unit 140 may be collectively referred to as “top-view imaging units”.

The third imaging unit 150 is an imaging unit for capturing an image, in a bottom view, of the semiconductor chip in a state held by the collet 122 of the bonding tool 120. As shown in the figure, with a stage surface 190a of the stage 190 taken as a dividing plane, the third imaging unit 150 is disposed in a space on a side opposite to a space in which the top-view imaging units are disposed.

The third imaging unit 150 includes a third optical system 151 and a third imaging element 152, and is disposed with an optical axis thereof oriented upward. The third imaging unit 150 is a general imaging unit disposed such that the third optical system 151 and the third imaging element 152 are orthogonal to the optical axis, and a focal plane 150a thereof is parallel to a light-receiving surface of the third imaging element 152. In addition, the focal plane 150a is set to coincide with the frame surface 330a of the lead frame 330. As a depth of field, the third optical system 151 takes a specific depth range across the focal plane 150a. Accordingly, in arrangement adjustment to align the focal plane 150a with the frame surface 330a, a deviation is permissible within the range of a depth of field D_{P}. In addition, in the following description, the third imaging unit 150 may be referred to as a “bottom-view imaging unit”.

The calibration unit 170 mainly includes an index drive motor 171, an index plate 172, and a calibration index 173. The calibration index 173 is a reference mark with a defined reference position, such as an intersection point of a cross mark. The index plate 172 is, for example, a thin plate of glass or transparent resin, with the calibration index 173 printed on one surface thereof. In other words, the calibration index 173 can be observed from both surface sides of the index plate 172. In the present embodiment, the calibration index 173 is printed on a surface of the index plate 172 that is on a side opposite to the surface opposed to the third imaging unit 150. In the present embodiment, the surface on which the calibration index 173 is printed is referred to as an index surface 173a. The calibration index 173 is not limited to being printed, but may also be provided by attaching a sticker or by scribing the surface of the index plate 172.

By swinging the index plate 172 around the Z-axis, the index drive motor 171 moves the calibration index 173 to the vicinity of a center of the field of view of the third imaging unit 150 or retracts the calibration index 173 from the field of view. With the calibration index 173 moved to the vicinity of the center of the field of view of the third imaging unit 150, the index surface 173a becomes the same plane as the frame surface 330a of the lead frame 330 and the focal plane 150a of the third imaging unit 150.

The stage 190 is disposed on a base 180, and by driving a stage drive motor 191, a height and an inclination with respect to the base 180 can be adjusted within a predetermined range. Adjustment of the height involves moving the stage surface 190a of the stage 190 in the Z-axis direction, and adjustment of the inclination involves rotating the stage surface 190a of the stage 190 around the X-axis and the Y-axis.

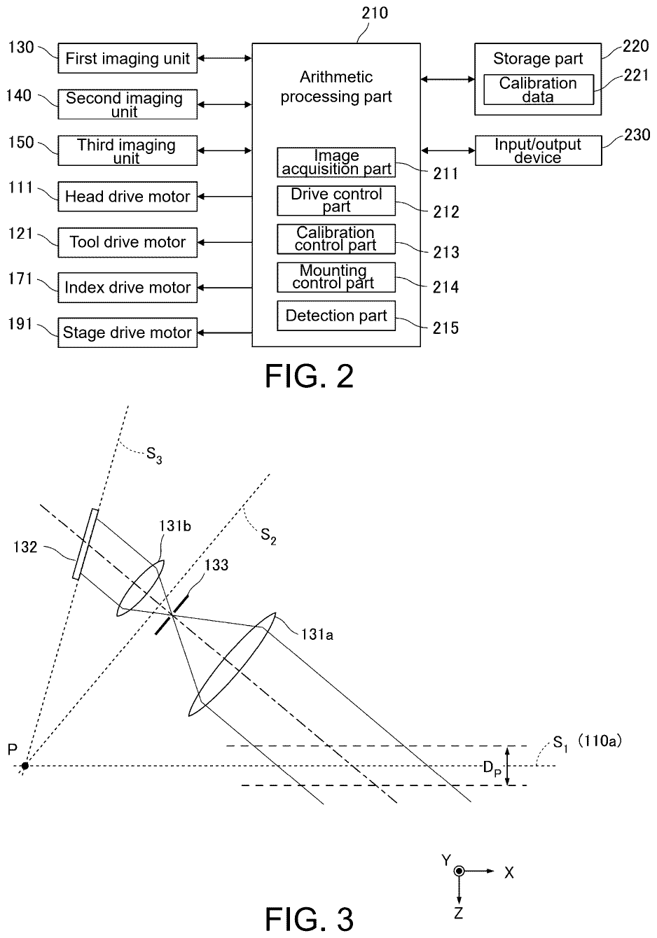

FIG. 2 is a system configuration diagram of the bonding apparatus 100. A control system of the bonding apparatus 100 is mainly composed of an arithmetic processing part 210, a storage part 220, an input/output device 230, a first imaging unit 130, a second imaging unit 140, a third imaging unit 150, a head drive motor 111, a tool drive motor 121, an index drive motor 171, and a stage drive motor 191.

The arithmetic processing part 210 is a processor (CPU: central processing unit) that performs control of the bonding apparatus 100 and execution processing of programs. The processor may be configured to work in conjunction with arithmetic processing chips such as an application specific integrated circuit (ASIC) or a graphics processing unit (GPU). The arithmetic processing part 210 reads out a bonding control program stored in the storage part 220 and executes various processings related to bonding control.

The storage part 220 is a non-volatile storage medium, and is, for example, composed of a hard disk drive (HDD). In addition to the bonding control program, the storage part 220 may also store various parameter values, functions, lookup tables, etc. used for control and calculation. In particular, the storage part 220 stores calibration data 221. The calibration data 221, which will be described in detail later, is data related to a calibration value for calibrating a difference between coordinate values calculated based on top-view images and coordinate values calculated based on a bottom-view image with respect to a same observation target.

The input/output device 230 includes, for example, a keyboard, a mouse, and a display monitor, and is a device that accepts menu operations performed by a user and presents information to the user. For example, the arithmetic processing part 210 may display the acquired top-view images or bottom-view image on a display monitor, which is one of the input/output devices 230.

The first imaging unit 130 executes imaging in response to an imaging request signal from the arithmetic processing part 210, and transmits a first top-view image outputted by the first imaging element 132 as an image signal to the arithmetic processing part 210. The second imaging unit 140 executes imaging in response to an imaging request signal from the arithmetic processing part 210, and transmits a second top-view image outputted by the second imaging element 142 as an image signal to the arithmetic processing part 210. The third imaging unit 150 executes imaging in response to an imaging request signal from the arithmetic processing part 210, and transmits a bottom-view image outputted by the third imaging element 152 as an image signal to the arithmetic processing part 210.

The head drive motor 111 moves the head part 110 in the horizontal plane direction and the height direction in response to a drive signal from the arithmetic processing part 210. The tool drive motor 121 moves the bonding tool 120 in the height direction and rotates the bonding tool 120 around the Z-axis in response to a drive signal from the arithmetic processing part 210. The index drive motor 171 swings the index plate 172 in response to a drive signal from the arithmetic processing part 210. The stage drive motor 191 moves the stage 190 in the Z-axis direction and rotates the stage 190 around the X-axis and the Y-axis in response to a drive signal from the arithmetic processing part 210.

The arithmetic processing part 210 also serves as a functional arithmetic part that executes various calculations according to processings instructed by the bonding control program. The arithmetic processing part 210 may function as an image acquisition part 211, a drive control part 212, a calibration control part 213, a mounting control part 214, and a detection part 215. The image acquisition part 211 transmits imaging request signals to the first imaging unit 130, the second imaging unit 140, and the third imaging unit 150, and acquires image signals of the first top-view image, the second top-view image, and the bottom-view image. By transmitting drive signals corresponding to control amounts to the head drive motor 111, the tool drive motor 121, the index drive motor 171, and the stage drive motor 191, the drive control part 212 displaces the head part 110, the bonding tool 120, the index plate 172, and the stage 190 to a target state. In addition, by transmitting drive signals to the pickup mechanism 510 and the inversion mechanism 520, a targeted semiconductor chip 310 is pushed up, or adsorbed to be inverted.

By controlling the image acquisition part 211, the drive control part 212, etc., the calibration control part 213 calculates the calibration value based on the top-view images of the calibration index 173 captured and outputted by the top-view imaging units, and the bottom-view image of the calibration index 173 captured and outputted by the bottom-view imaging unit. By controlling the image acquisition part 211, the drive control part 212, etc., the mounting control part 214 recognizes the reference position of the semiconductor chip 310 based on the bottom-view image of the semiconductor chip 310 held by the bonding tool 120 captured and outputted by the bottom-view imaging unit. Then, the bonding tool 120 is caused to place and bond the semiconductor chip 310 on a planned placement area, such that the reference position matches a target position determined based on the calibration value and the top-view images of the planned placement area, on which the semiconductor chip 310 is to be placed, captured and outputted by the top-view imaging units.

The head part 110 is displaced, and the first imaging unit 130 and the second imaging unit 140 are respectively caused to capture and output a first top-view image and a second top-view image of multiple spots on the stage surface 190a or a work plane such as the frame surface 330a. Using height information of each of the multiple spots calculated based on the first top-view image and the second top-view image, the detection part 215 detects an inclination of the stage surface or the work plane with respect to the reference plane. Specific controls and processings of the calibration control part 213, the mounting control part 214, and the detection part 215 will be described in detail later.

FIG. 3 is a view for illustrating a Scheimpflug optical system adopted in the first imaging unit 130. A similar Scheimpflug optical system is also adopted in the second imaging unit 140, but herein, the Scheimpflug optical system of the first imaging unit 130 will be described as a representative example.

In FIG. 3, a plane Si is the focal plane 110a, which is parallel to the reference plane. A virtual plane S₂ is a plane that includes a principal plane of the first optical system 131, which takes an object-side lens group 131a and an image-side lens group 131b as constituent groups. A plane S₃ is a plane that includes the light-receiving surface of the first imaging element 132. In the present embodiment, the Scheimpflug optical system includes the first optical system 131 and the first imaging element 132, which are disposed to satisfy the Scheimpflug condition. An arrangement satisfying the Scheimpflug condition refers to an arrangement in which the plane S₁, the virtual plane S₂, and the virtual plane S₃ intersect each other on a common straight line P.

An aperture 133 is disposed between the object-side lens group 131a and the image-side lens group 131b, and limits a passing light beam. A depth of field D_{P} may be adjusted by a diameter of the aperture 133. Accordingly, if a target work area for performing a mounting work is located within the depth of field, the work area can be imaged in a focused state.

The second imaging unit 140 includes a configuration similar to the first imaging unit 130 and is disposed at the head part 110 symmetrically with respect to a YZ plane including a center axis of the bonding tool 120. Accordingly, similar to the first imaging unit 130, the second imaging unit 140 can also capture an image of the target work area in a focused state. The focal plane of the first imaging unit 130 and the focal plane of the second imaging unit 140 preferably coincide at the focal plane 110a. However, even if there is a deviation, the target work area can be imaged by both in a focused state as long as the depths of field thereof partially overlap with each other.

Upon adopting imaging units that adopt such a Scheimpflug optical system, the area directly below the bonding tool 120 can be observed from oblique directions. Accordingly, even in a state in which the semiconductor chip 310 is held by the bonding tool 120 and is moved by the bonding tool 120 to directly above a die pad, which is the planned placement area thereof, the die pad can be observed with the top-view imaging units. In other words, after moving the bonding tool 120 to directly above the die pad, which is the planned placement area, the target position at which the semiconductor chip 310 is placed can be determined based on the top-view images outputted by the top-view imaging units. Thus, since it is only necessary to move the semiconductor chip 310 from this state to the target position, movement of the head part 110 and the bonding tool 120 can be significantly reduced, and it becomes possible to achieve reduction in position deviation associated with movement and shortening of a lead time.

However, it is learned that, in an imaging unit adopting a Scheimpflug optical system, due to structural properties of the optical system, the output image is prone to displacement in the plane direction as the optical system or the imaging element displaces along with temperature changes in the surrounding environment. In other words, it is learned that the image shifts due to temperature changes in the surrounding environment. Such a phenomenon may introduce an error in the target position in the case of determining the target position at which the semiconductor chip 310 is placed based on the top-view images. Accordingly, in the case where the semiconductor chip is to be bonded to the target position with a higher precision, a compensation processing may be executed to absorb such an error. Specifically, for example, at a predetermined timing at which a temperature change in the surrounding environment is anticipated, a calibration processing is executed to calculate a calibration value for calibrating the difference between the coordinate value calculated based on the top-view images and the coordinate value calculated based on the bottom-view image with respect to the same observation target. Then, in the mounting processing of bonding the semiconductor chip 310 to the target position of the lead frame 330, a precise target position is determined using the calculated calibration value. The calibration processing and the mounting processing will be sequentially described below.

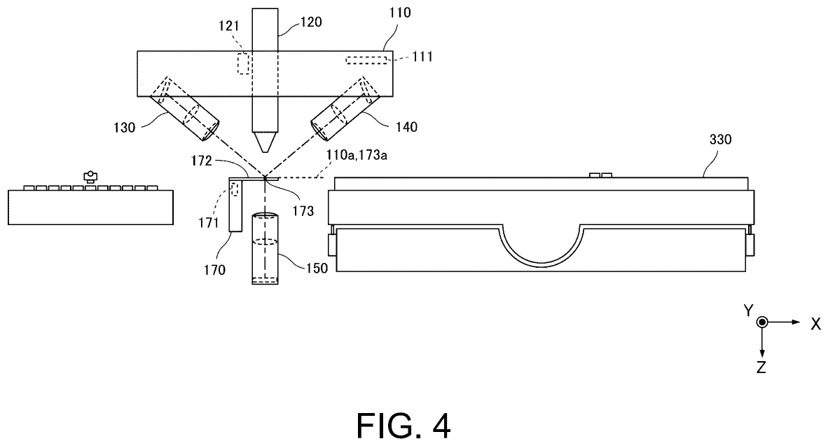

The calibration processing is executed by the calibration control part 213. The calibration control part 213 first causes the first imaging unit 130, the second imaging unit 140, and the third imaging unit 150 to capture images of the calibration index 173. FIG. 4 is a view showing the three imaging units capturing images of the calibration index 173.

As shown in the figure, when starting the calibration processing, the calibration control part 213 moves the index plate 172 into the field of view of the third imaging unit 150 by driving the index drive motor 171 via the drive control part 212. Upon moving the index plate 172 into the field of view of the third imaging unit 150, the calibration index 173 provided on the index plate 172 is located approximately at the center with respect to the field of view of the fixed third imaging unit 150.

Next, by driving the head drive motor 111 via the drive control part 212, the calibration control part 213 moves the head part 110 such that the focal plane 110a of the top-view imaging units coincides with the index surface 173a, and the calibration index 173 is located directly below the bonding tool 120. The bonding tool 120 is retracted to a position that does not intrude into the field of view of the top-view imaging units.

With respective components disposed in this manner, the calibration control part 213 acquires, via the image acquisition part 211, a first top-view image from the first imaging unit 130, a second top-view image from the second imaging unit 140, and a bottom-view image from the third imaging unit 150. Then, from image coordinates of the image of the calibration index 173 respectively reflected in the first top-view image and the second top-view image, three-dimensional coordinates (Xₕᵣ, Yₕᵣ, Zₕᵣ) of the calibration index 173 are calculated. In addition, from image coordinates of the image of the calibration index 173 reflected in the bottom-view image, three-dimensional coordinates (Xₛᵣ, Yₛᵣ, Zₛᵣ) of the calibration index 173 are calculated. If the top-view imaging units are not affected by temperature changes in the surrounding environment, and a state in which the coordinates between the imaging units are correctly adjusted in an initial state of the bonding apparatus 100 is maintained, at least Xₕᵣ=Xₛᵣ and Yₕᵣ=Yₛᵣ should hold true.

However, as described above, as some time passes after use of the bonding apparatus 100 starts, the three-dimensional coordinates calculated from the top-view images come to include an error due to the influence of temperature changes in the surrounding environment. Thus, (ΔX, ΔY), which is the error, is taken as the calibration value. Specifically, the error may be expressed as a difference, where ΔX=Xₛᵣ−Xₕᵣ and ΔY=Yₛᵣ−Yₕᵣ. With the calibration value calculated in this manner, if images of an observation target are later captured by the top-view imaging units, and three-dimensional coordinates calculated from the top-view images are (Xₕₜ, Yₕₜ, Zₕₜ), the three-dimensional coordinates may be corrected to (Xₕₜ+ΔX, Yₕₜ+ΔY, Zₕₜ) by taking into account the calibration value. The corrected coordinate value may be said to contain no error with respect to a coordinate value that would be calculated from a bottom-view image obtained in the case where the same observation target could be imaged by the bottom-view imaging unit.

The calibration control part 213 stores the calibration value calculated in this manner as calibration data 221 to the storage part 220. The calibration data 221 is referred to in the mounting processing to be described later until it is evaluated that the temperature in the surrounding environment may have changed further and a re-calibration processing is necessary. In other words, upon evaluating that a re-calibration processing is necessary, the calibration control part 213 repeats the above processing to update the calibration value.

An example of evaluation that a re-calibration processing is necessary may be a timing at which the mounting control part 214 completes bonding of a preset lot of semiconductor chips 310. Specifically, the calibration control part 213 may execute the calibration processing in accordance with the timing at which a new lot of semiconductor chips 310 is fed to the chip feeding apparatus 500. In addition, a work time of the bonding work executed by the mounting control part 214 may be taken as a guide. For example, it may be determined to execute the calibration processing in the case where the bonding work has been continuously executed for 60 minutes. Furthermore, a temperature detection part detecting temperatures of the top-view imaging units may be provided at the head part 110, and the above timing may be a timing at which the temperature detection part detects a preset temperature. Specifically, multiple temperatures are set in advance, and the calibration processing is executed in the case of detecting that the surrounding temperature has fluctuated across these temperatures. With the calibration value updated in this manner, it becomes possible to suppress the error of the coordinate value calculated from the top-view images within a specific range over the period in which the mounting processing is continued.

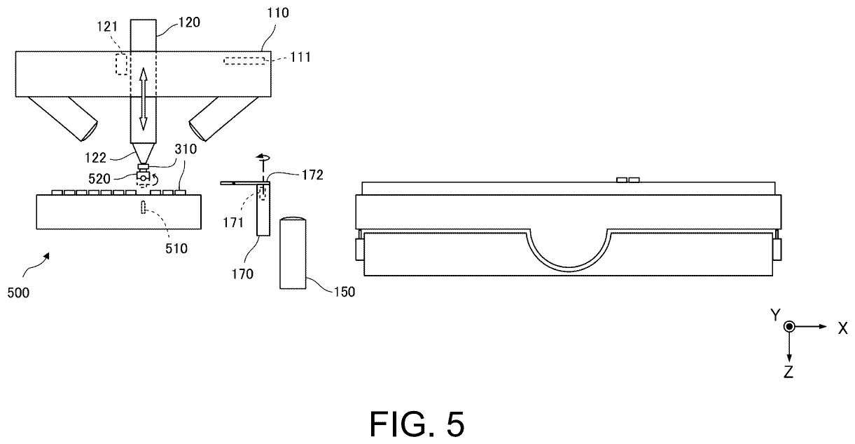

The mounting processing is executed by the mounting control part 214. First, the mounting control part 214 picks up the target semiconductor chip 310. FIG. 5 is a view showing the bonding tool 120 picking up the semiconductor chip 310.

The mounting control part 214 moves the head part 110 to an upper part of the chip feeding apparatus 500 by driving the head drive motor 111 via the drive control part 212, and lowers the bonding tool 120 by driving the tool drive motor 121. In parallel with this, among the semiconductor chips 310 placed on the chip feeding apparatus 500, the pickup mechanism 510 pushes up the semiconductor chip 310 serving as a mounting target toward the inversion mechanism 520, and the inversion mechanism 520 adsorbs and inverts the semiconductor chip 310. Then, the lowered bonding tool 120 adsorbs and picks up the semiconductor chip 310 by the collet 122, and the bonding tool 120 is raised.

In the case where the index plate 172 is located within the field of view of the third imaging unit 150, the mounting control part 214 retracts the index plate 172 from the field of view of the third imaging unit 150 about the time of the work of pickup of the semiconductor chip 310 by the bonding tool 120. Specifically, the mounting control part 214 moves the index plate 172 by driving the index drive motor 171 via the drive control part 212.

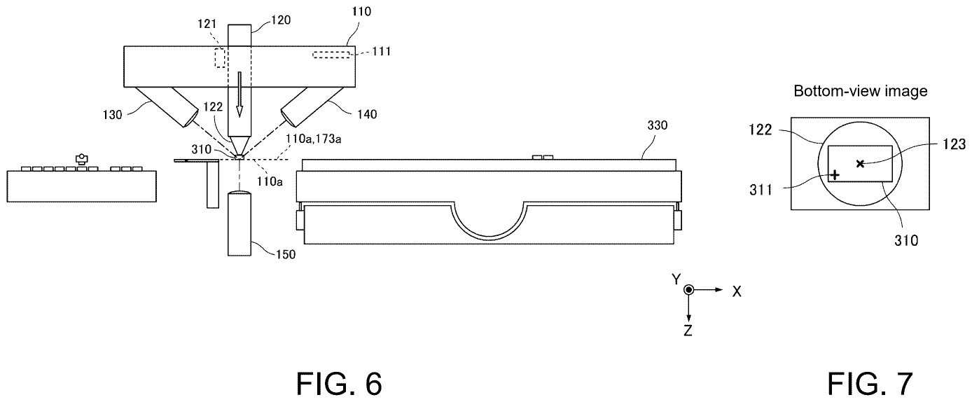

Next, the mounting control part 214 causes the third imaging unit 150 to capture an image of the semiconductor chip 310 adsorbed by the bonding tool 120. FIG. 6 is a view showing the third imaging unit 150 capturing an image of the semiconductor chip 310 adsorbed by the bonding tool 120.

By driving the head drive motor 111 via the drive control part 212, the mounting control part 214 moves the head part 110 such that the focal plane 110a of the top-view imaging units coincides with the index surface 173a, and the third imaging unit 150 is located directly below the bonding tool 120. Then, by driving the tool drive motor 121, the bonding tool 120 is lowered such that a planned contact surface of the held semiconductor chip 310 to contact the lead frame 330 coincides with the index surface 173a. After such adjustment of the arrangement is completed, the mounting control part 214 causes the third imaging unit 150 to capture an image of the semiconductor chip 310 held by the bonding tool 120 via the image acquisition part 211.

FIG. 7 is a view schematically showing a bottom-view image of the semiconductor chip 310 held by the bonding tool 120 captured and outputted by the third imaging unit 150. In the figure, the image of each imaged subject is directly labeled with the reference sign of the corresponding imaged subject for description.

As described above, the bonding tool 120 picks up and holds the semiconductor chip 310 prepared by the chip feeding apparatus 500 by adsorption with the collet 122. At this time, the bonding tool 120 is to adsorb the center of the semiconductor chip 310 in a preset orientation, but actually, there are also cases where the semiconductor chip 310 is adsorbed including a deviation with respect thereto. Thus, the mounting control part 214 confirms at which position and in which orientation the semiconductor chip 310 is actually held, and recognizes the reference position for placing the semiconductor chip 310 onto the lead frame 330.

Since the bottom-view image shown in FIG. 7 is an image captured by the third imaging unit 150 looking up at the semiconductor chip 310, the collet 122 holding the semiconductor chip 310 is also reflected in the image. Thus, the mounting control part 214 calculates image coordinates of a collet center 123 by detecting a circle which is the outline of the collet 122.

In addition, in the present embodiment, the semiconductor chip 310 is provided with a chip reference mark 311 on the planned contact surface to contact the lead frame 330, and the mounting control part 214 calculates image coordinates of the chip reference mark 311 reflected in the bottom-view image. From the image coordinates of the collet center 123 and the image coordinates of the chip reference mark 311 calculated in this manner, the mounting control part 214 can recognize at which position and in which orientation the semiconductor chip 310 is actually held with respect to the collet 122. For example, if the position at which the chip reference mark 311 is provided is taken as the reference position for placing the semiconductor chip 310 onto the lead frame 330, the mounting control part 214 can calculate the three-dimensional coordinates of the reference position of the semiconductor chip 310 of the time point of capturing the bottom-view image. Accordingly, even if the bonding tool 120 and the head part 110 are later moved, as long as the collet 122 continues to hold the semiconductor chip 310, the three-dimensional coordinates of the reference position can be tracked.

After recognizing the three-dimensional coordinates of the reference position, by driving the tool drive motor 121, the mounting control part 214 raises the bonding tool 120 to a position at which the held semiconductor chip 310 retracts from the field of view of the top-view imaging units. Then, by driving the head drive motor 111, the head part 110 is moved such that the bonding tool 120 is directly above the die pad 320 on which the semiconductor chip 310 is to be placed, and the focal plane 110a of the top-view imaging units coincides with the frame surface 330a, which is a planned placement surface of the lead frame 330. Raising of the bonding tool 120 and movement of the head part 110 may be performed in parallel.

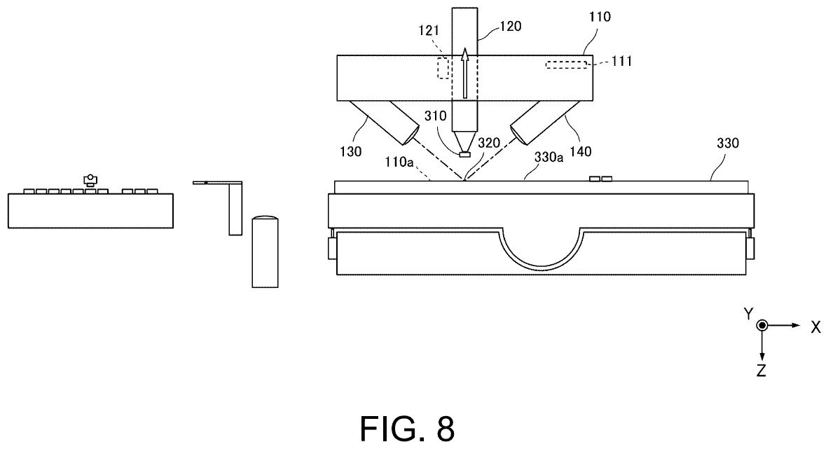

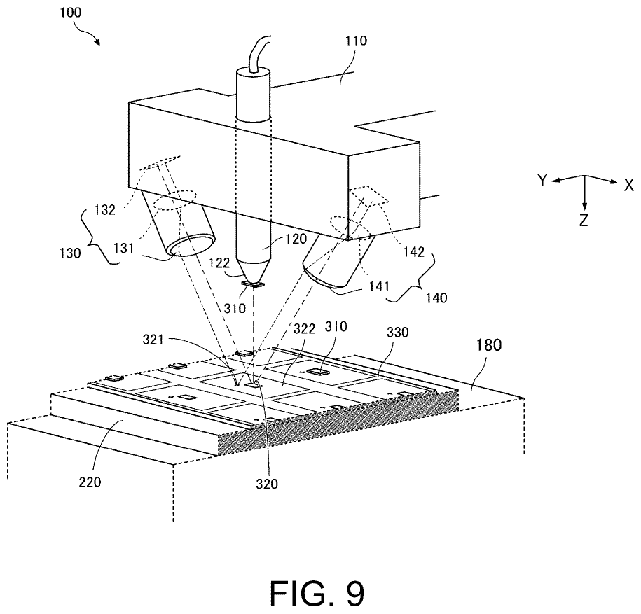

FIG. 8 is a view showing the first imaging unit 130 and the second imaging unit 140 capturing images of the work area of the lead frame 330 in a state in which the head part 110 and the bonding tool 120 are disposed as described above. In addition, FIG. 9 is a partial perspective view of FIG. 8. In the present embodiment, the lead frame 330 has one die pad 320 in each unit area 322 that will be cut out and enclosed in one package. In the present embodiment, the unit area 322 is a work area in which the bonding work is performed and includes the planned placement area on which the semiconductor chip 310 is placed. In addition, the frame surface 330a is a work plane that includes the work area. Each unit area 322 is provided with a pad reference mark 321 indicating a reference position thereof. In the present embodiment, the pad reference mark 321 may be recognized as a specific spot on the work plane.

In the state of arrangement shown in FIG. 8 and FIG. 9, the first imaging unit 130 and the second imaging unit 140 can each perceive the die pad 320 and the pad reference mark 321 included in the same unit area 322 within the field of view to capture an image in a focused state. Using the first top-view image outputted by the first imaging unit 130 and the second top-view image outputted by the second imaging unit 140, the mounting control part 214 calculates the coordinates of the target position that the reference position should match when placing the semiconductor chip 310 on the die pad 320.

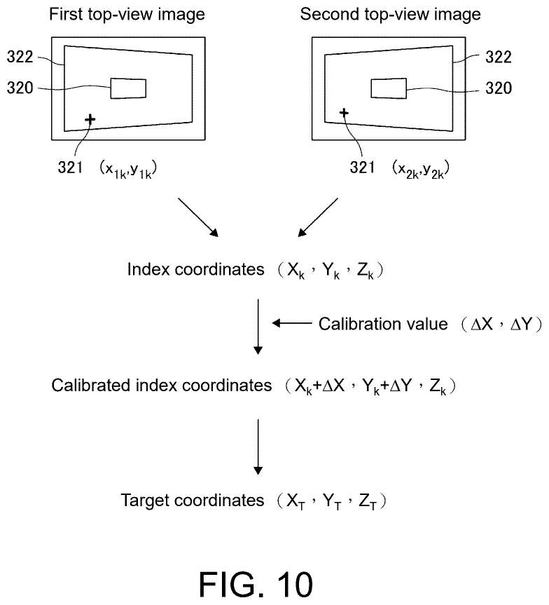

FIG. 10 is a view showing a procedure up to calculating the target coordinates at which the semiconductor chip 310 is placed from the first top-view image and the second top-view image. Since the first imaging unit 130 captures an image of them from the pad reference mark 321 side with respect to the die pad 320, in the first top-view image, which is the output image, the unit area 322 is reflected in a trapezoidal shape that expands toward the pad reference mark 321 side. In contrast, since the second imaging unit 140 captures an image of them from the side opposite to the pad reference mark 321 with respect to the die pad 320, in the second top-view image, which is the output image, the unit area 322 is reflected in a trapezoidal shape that narrows toward the pad reference mark 321 side.

The mounting control part 214 determines image coordinates (x₁ₖ, y₁ₖ) of the pad reference mark 321 from the first top-view image, and also determines image coordinates (x₂ₖ, y₂ₖ) of the pad reference mark 321 from the second top-view image. Then, for example, by referring to a conversion table that converts image coordinates into three-dimensional coordinates, index coordinates (Xₖ, Yₖ, Zₖ), which are the three-dimensional coordinates of the pad reference mark 321, are calculated from the image coordinates. The coordinate value of the index coordinates is a provisional target position for calculating the precise target position, and as described above, also includes an error due to the influence of temperature changes in the surrounding environment. Thus, the calibration value (ΔX, ΔY) is read from the calibration data 221 to perform correction. The coordinate value of the corrected index coordinates (Xₖ+ΔX, Yₖ+ΔY, Zₖ) obtained in this manner may be expected to contain no error with respect to the spatial coordinates calculated from the bottom-view image.

Since the relative positions between the pre-set target position of the die pad 320 and the pad reference mark 321 are known, the mounting control part 214 can accurately calculate the coordinates (X_{T}, Y_{T}, Z_{T}) of the target position from the corrected index coordinates (Xₖ+ΔX, Yₖ+ΔY, Zₖ).

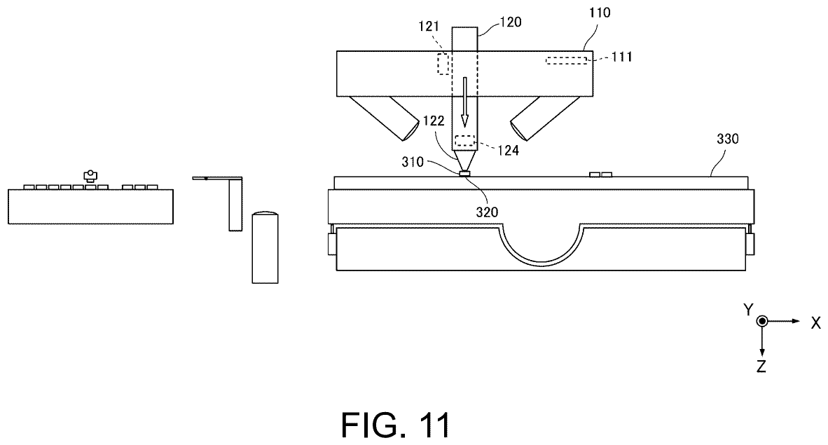

After the coordinates of the target position are confirmed, the semiconductor chip 310 is placed and bonded to the target position. FIG. 11 is a view showing the bonding tool 120 placing and bonding the semiconductor chip 310 to the target position.

As described above, the mounting control part 214 tracks and learns about the three-dimensional coordinates of the reference position of the semiconductor chip 310 in response to movement of the bonding tool 120 and the head part 110, and moves the semiconductor chip 310 such that the reference position matches the target position of the die pad 320. Specifically, the XY-direction position of the head part 110 is finely adjusted by driving the head drive motor 111 via the drive control part 212, and the rotation amount of the bonding tool 120 around the Z-axis is finely adjusted by driving the tool drive motor 121. Then, in a state in which the X-coordinate and the Y-coordinate of the reference position respectively coincide with the X-coordinate and the Y-coordinate of the target position, the bonding tool 120 is lowered, and the semiconductor chip 310 is placed on the die pad 320. Thereafter, while pressing the semiconductor chip 310 by the tip of the collet 122, the semiconductor chip 310 is heated by the heater 124 and adhered to the die pad 320.

In the present embodiment, the focal plane 110a of the top-view imaging units and the index surface 173a of the calibration index 173 are aligned with the frame surface 330a of the lead frame 330 to calculate the calibration value. In other words, the Z-direction position of the head part 110 when calculating the calibration value is the same as the Z-direction position of the head part 110 when the top-view imaging units capture images of the chip reference mark 311. In addition, as described with reference to FIG. 6 and FIG. 7, the planned contact surface of the semiconductor chip 310 held by the collet 122 is aligned with the frame surface 330a of the lead frame 330 to calculate the three-dimensional coordinates of the chip reference mark 311. In other words, the Z-direction position of the bonding tool 120 when calculating the three-dimensional coordinates of the chip reference mark 311 is the same as the Z-direction position of the bonding tool 120 when placing the semiconductor chip 310 on the die pad 320.

Accordingly, it is not required to consider the error in the XY direction between the actual three-dimensional coordinates and the recognized three-dimensional coordinates that may occur in the case of moving the head part 110 and the bonding tool 120 in the Z direction. For example, in the state of FIG. 8, the bonding tool 120 holds the semiconductor chip 310 and retracts from the field of view of the top-view imaging units, but there are also cases where, in this state, the actual X-coordinate and Y-coordinate of the reference position do not coincide with the X-coordinate and the Y-coordinate recognized by the mounting control part 214 due to the influence of play between elements of the moving mechanism that moves the bonding tool 120 up and down. However, as shown in FIG. 11, the height of the bonding tool 120 when placing the semiconductor chip 310 on the frame surface 330a is the same as the height of the bonding tool 120 when calculating the three-dimensional coordinates of the chip reference mark 311, and the error factor due to the moving mechanism is eliminated. In other words, the actual X-coordinate and Y-coordinate of the reference position when placing the semiconductor chip 310 on the frame surface 330a will coincide with the X-coordinate and the Y-coordinate recognized by the mounting control part 214. From this viewpoint, it is effective to align the focal plane 110a and the index surface 173a of the calibration index 173 with the frame surface 330a in the case of calculating the calibration value, and to align the planned contact surface of the semiconductor chip 310 with the frame surface 330a in the case of calculating the three-dimensional coordinates of the chip reference mark 311.

In addition, in the case of aligning the frame surface 330a and the index surface 173a, the height of the index surface 173a may be adjusted to align with the frame surface 330a, or the height of the frame surface 330a may be adjusted to align with the index surface 173a. In the case of adjusting the height of the index surface 173a, for example, the index surface 173a may be displaced by driving of the index drive motor 171 in the Z-axis direction together with the third imaging unit 150 to maintain the state in which the index surface 173a and the focal plane 150a coincide. In the case of adjusting the height of the frame surface 330a, for example, the frame surface 330a may be displaced by driving of the stage drive motor 191 in the Z-axis direction.

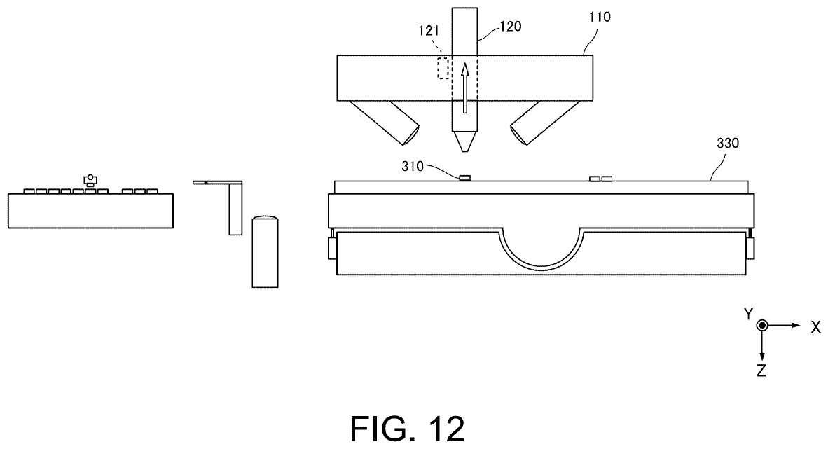

FIG. 12 is a view showing the bonding tool 120 retracting. As shown in the figure, after bonding of the semiconductor chip 310 is completed, the mounting control part 214 raises the bonding tool 120 by driving the tool drive motor 121 via the drive control part 212. In the case of further bonding a new semiconductor chip 310, returning to the state of FIG. 5, the processing is repeated.

In the above calibration processing and mounting processing, it has been described that the focal plane 150a of the top-view imaging units, the index surface 173a of the calibration index 173, and the frame surface 330a of the lead frame 330 are respectively adjusted to be parallel to the horizontal plane, which is an example of the reference plane, and the index surface 173a and the frame surface 330a are adjusted to be the same plane. However, for example, in the case where the stage 190 includes a mechanism capable of adjusting the height and the inclination of the stage surface 190a, or where the front and back surfaces of the lead frame 330 are not parallel to each other due to manufacturing variations, the frame surface 330a, which is the work plane of the mounting work, may be inclined from the reference plane.

In the mounting processing of the semiconductor chip, inclination of the work plane may cause various issues. For example, in the present embodiment, if the frame surface 330a is inclined with respect to the reference plane, the following situation may occur: even though the top-view imaging units can focus on one work area, the top-view imaging units cannot focus on another work area on the same frame surface 330a unless the height of the head part 110 is re-adjusted. Consequently, a process for re-adjusting the height of the head part 110 would be required each time a work area that cannot be focused on appears, which contradicts the demand for shortening of the lead time. Particularly, when the calibration value is used for a high precision as in the present embodiment, there are also cases where it is necessary to execute the re-calibration processing to calculate a correction value for the height of such a work area.

In the present embodiment, as described with reference to FIG. 10, when calculating the planar coordinates (Xₖ, Yₖ) of the pad reference mark 321 provided in the unit area 322, the mounting control part 214 simultaneously calculates the height coordinate Zₖ of the pad reference mark 321. In addition, to confirm at which position and in which orientation the lead frame 330 is placed on the stage surface 190a, an index provided on the stage surface 190a or an index provided at a periphery of the lead frame 330 may be observed to calculate planar coordinates thereof. In such a case, the mounting control part 214 also simultaneously calculates the height coordinate. If three or more indices serving as targets for calculating three-dimensional coordinates are not arranged on a straight line, an inclination of a plane on which the multiple indices are provided can be detected by using the three-dimensional coordinates calculated from these indices.

The bonding apparatus 100 of the present embodiment includes a detection part 215 that detects the inclination of the stage surface 190a or the frame surface 330a with respect to the reference plane using the height coordinates calculated together when the mounting control part 214 calculates the in-plane coordinates (i.e., planar coordinates) of three or more specific spots of the stage surface 190a or the frame surface 330a in the series of works of mounting the semiconductor chip 310 in this manner.

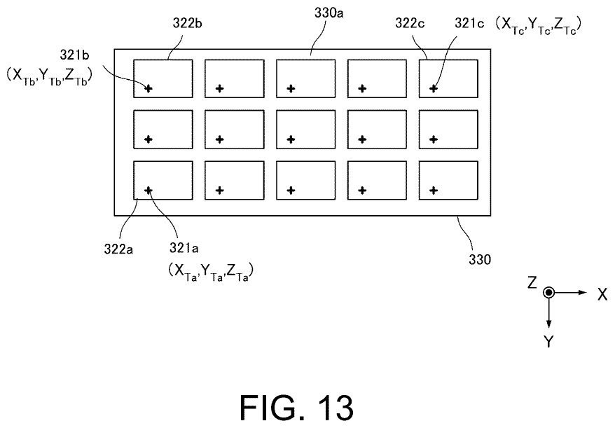

FIG. 13 is a view illustrating a detection principle of detecting the inclination of the frame surface 330a with respect to the reference plane. Specifically, FIG. 13 is a view observing a schematically represented lead frame 330 in a top view. The lead frame 330 has a first unit area 322a at a lower left end, a second unit area 322b at an upper left end, and a third unit area 322c at an upper right end. Herein, it is assumed that the semiconductor chip 310 is continuously mounted in a sequence of the first unit area 322a=the second unit area 322b→the third unit area 322c, and then sequentially mounted to other unit areas.

After the mounting control part 214 acquires three-dimensional coordinates (X_{Ta}, Y_{Ta}, Z_{Ta}) of a first pad reference mark 321a provided in the first unit area 322a and mounts the semiconductor chip 310 based on the three-dimensional coordinates, the detection part 215 receives the three-dimensional coordinates from the mounting control part 214. Similarly, three-dimensional coordinates (X_{Tb}, Y_{Tb}, Z_{Tb}) of a second pad reference mark 321b provided in the second unit area 322b and three-dimensional coordinates (X_{Tc}, Y_{Tc}, Z_{Tc}) of a third pad reference mark 321c provided in the third unit area 322c are received from the mounting control part 214. Then, an inclination of the frame surface 330a is calculated using the three sets of three-dimensional coordinates. Herein, the inclination may be calculated as a normal vector of the frame surface 330a, or may be calculated as respective inclination angles around the X-axis and around the Y-axis.

In addition, in the case of calculating the inclination using three-dimensional coordinates of four points or more, a regression plane that fits the three-dimensional coordinates may be determined and then an inclination of the regression plane may be calculated. In addition, in the above description, the information of the calculated planar coordinates (X_{Tx}, Y_{Tx}) of the pad reference mark 321 is also used to calculate the inclination. However, since the position of each pad reference mark 311 on the lead frame 330 within the frame surface 330a is known, the inclination may also be calculated by combining this known information with the calculated height coordinate Zₖ . In addition, in the above description, three pad reference marks 321, each provided at the periphery of the lead frame 330, are selected to enhance the precision of the calculated inclination. However, the reference marks 321 measured for calculating the inclination are not limited thereto.

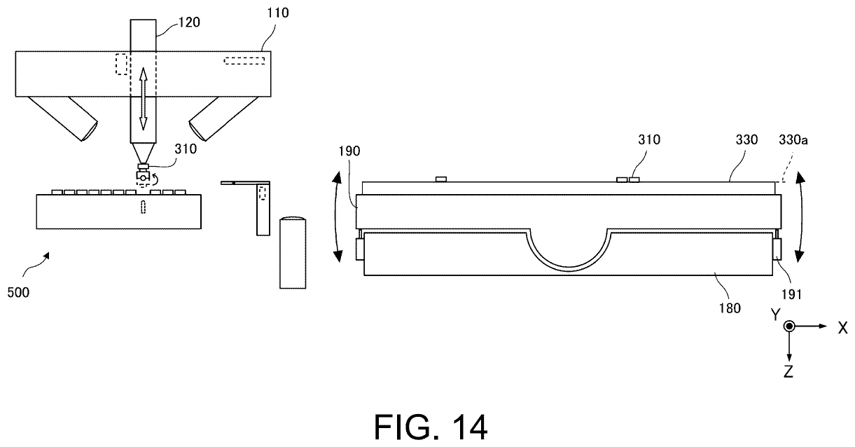

FIG. 14 is a view showing performing parallel adjustment of the frame surface 330a. After the detection part 215 calculates the inclination of the frame surface 330a, the mounting control part 214 performs parallel adjustment to configure the frame surface 330a to be parallel to the reference plane by driving the stage drive motor 191 via the drive control part 212, before next executing the mounting processing to mount the semiconductor chip 310. At this time, as shown in the figure, the mounting control part 214 may simultaneously perform the work of picking up, by the bonding tool 120, the semiconductor chip 310 to be mounted next from the chip feeding apparatus 500. As described above, if the inclination of the frame surface 330a can be eliminated in the series of mounting processings of mounting multiple semiconductor chips 310, the lead time required for the mounting processing can be shortened, and a mounting processing with a higher precision can be achieved.

However, depending on the degree of inclination of the frame surface 330a, there are also cases where, in some unit areas, the pad reference mark does not fall within the depth of field D_{P} of the top-view imaging units, and the three-dimensional coordinates cannot be calculated. In such cases, the mounting control part 214 moves the head part 110 up and down to bring the unit area within the range of the depth of field D_{P}, and then calculates the three-dimensional coordinates of the pad reference mark provided in the unit area. At this time, mounting of the semiconductor chip 310 to this unit area is suspended. Then, the detection part 215 calculates the inclination of the frame surface 330a based on the three-dimensional coordinates. The mounting control part 214 drives the stage drive motor 191 based on this result to eliminate the inclination and adjust the frame surface 330a to be the same plane as the index surface 173a. Thereafter, the head part 110 is moved up and down again to calculate the three-dimensional coordinates of the pad reference mark, and the semiconductor chip 310 is mounted to the unit area based on the three-dimensional coordinates.

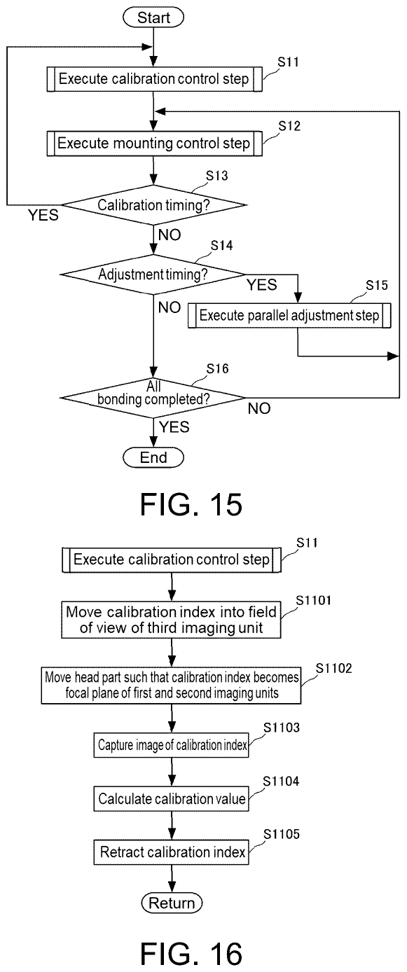

Next, an overall bonding procedure including the calibration processing, the mounting processing, and the parallel adjustment processing described above will be summarized according to flowcharts. FIG. 15 is a flowchart illustrating the bonding procedure of the semiconductor chip 310.

In step S11, the calibration control part 213 starts a calibration control step to perform the calibration processing. This will be described in detail later as a sub-flow. In the case where the mounting processing is started from an initial state in which the coordinates between the imaging units are correctly adjusted, the initial calibration control step may be skipped.

After the calibration control part 213 ends execution of the calibration control step, proceeding to step S12, the mounting control part 214 starts a mounting control step to perform the mounting processing. This will be described in detail later as a sub-flow.

After the mounting control part 214 ends execution of the mounting control step, proceeding to step S13, the calibration control part 213 determines whether the state of the bonding apparatus 100 at this time point satisfies a condition of a calibration timing set in advance. The condition of the calibration timing set in advance is a condition under which a re-calibration processing may be considered necessary. For example, as described above, candidates of the set condition include the number of lots for which the processing has been completed, the work time of the bonding work, the temperature detected by the temperature detection part, etc.

In step S13, in the case where the calibration control part 213 determines that the condition is satisfied, the process returns to step S11. In the case of determining that the condition is not satisfied, the process proceeds to step S14. In the case of proceeding to step S14, the mounting control part 214 determines whether the state of the bonding apparatus 100 at this time point satisfies a condition of a parallel adjustment timing set in advance. The condition of the parallel adjustment timing set in advance is a condition under which the parallel adjustment processing may be considered necessary. For example, as described above, candidates for the set condition include the time point at which mounting of the semiconductor chip 310 to the three unit areas 322 set at the periphery is ended, or the time point at which mounting of a predetermined number of semiconductor chips 310 or a predetermined number of lots of semiconductor chips 310 is ended. As described above, the time point at which the lead frame 330 is placed on the stage 190 may also be taken as the set condition.

In step S14, in the case where the mounting control part 214 determines that the condition is satisfied, proceeding to step S15, the detection part 215 starts a parallel adjustment step. After the parallel adjustment step is completed, the process returns to step S12. In the case of determining that the condition is not satisfied in step S14, the process proceeds to step S16.

Upon proceeding to step S16, the mounting control part 214 determines whether the planned mounting processing has all been completed. If it is determined that there are remaining semiconductor chips 310 to be subjected to the mounting processing, the process returns to step S12, and if it is determined that the mounting processing has all been completed, the series of processings is ended.

FIG. 16 is a sub-flowchart illustrating the procedure of the calibration control step. In the calibration control step, the processing described with reference to FIG. 4 is mainly executed. In step S1101, the calibration control part 213 moves the index plate 172 to bring the calibration index 173 to the center of the field of view of the third imaging unit 150. Next, in step S1102, the calibration control part 213 moves the head part 110 such that the calibration index 173 is at the focal plane 110a of the first imaging unit 130 and the second imaging unit 140, and the calibration index 173 is located directly below the bonding tool 120.

Proceeding to step S1103, the calibration control part 213 causes each imaging unit to capture an image via the image acquisition part 211, and acquires a first top-view image from the first imaging unit 130, a second top-view image from the second imaging unit 140, and a bottom-view image from the third imaging unit 150. Then, in subsequent step S1104, three-dimensional coordinates of the calibration index 173 are calculated based on image coordinates of the image of the calibration index 173 respectively reflected in the first top-view image and the second top-view image, and three-dimensional coordinates of the calibration index 173 are calculated based on the image of the calibration index 173 reflected in the bottom-view image. The calibration control part 213 calculates, as a calibration value, a difference in the XY plane direction among the respective three-dimensional coordinates calculated in this manner. The calculated calibration value is stored to the storage part 220 as calibration data 221.

Thereafter, in step S1105, the calibration control part 213 moves the index plate 172 to retract the calibration index 173 from the field of view of the third imaging unit 150. After retraction of the calibration index 173 is completed, the process returns to the main flow. Retraction of the calibration index 173 may also be performed during the subsequent mounting

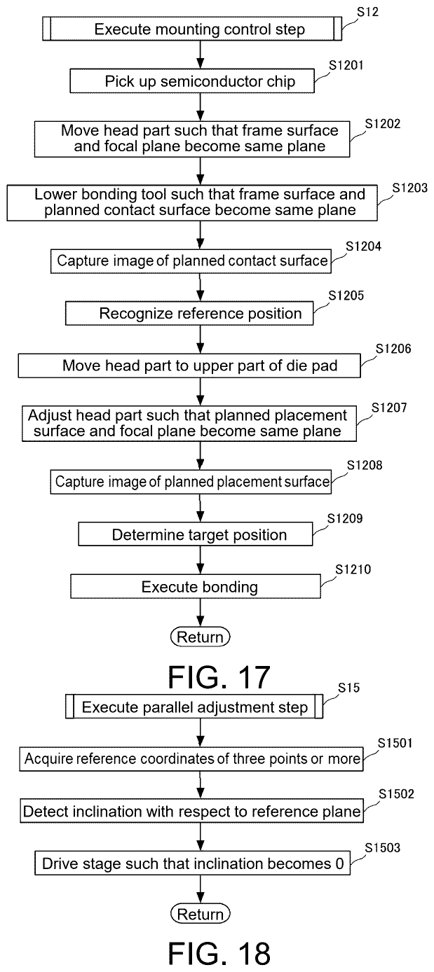

FIG. 17 is a sub-flowchart illustrating the procedure of the mounting control step. In the mounting control step, the processing described with reference to FIG. 5 to FIG. 12 is mainly executed.

In step S1201, the mounting control part 214 moves the head part 110 to the upper part of the chip feeding apparatus 500 and lowers the bonding tool 120. Then, among the semiconductor chips 310 placed on the chip feeding apparatus 500, the semiconductor chip 310 serving as the mounting target is inverted by the pickup mechanism 510 and the inversion mechanism 520 and is adsorbed and picked up by the collet 122, and the bonding tool 120 is raised.

In step S1202, the mounting control part 214 moves the head part 110 such that the focal plane 110a of the top-view imaging units coincides with the index surface 173a, and the third imaging unit 150 is located directly below the bonding tool 120. Furthermore, in step S1203, the bonding tool 120 is lowered such that the planned contact surface of the held semiconductor chip 310 to contact the lead frame 330 coincides with the index surface 173a.

After such arrangement adjustment is completed, in step S1204, the mounting control part 214 causes the third imaging unit 150 to capture an image of the planned contact surface of the semiconductor chip 310 held by the bonding tool 120. Then, in step S1205, the bottom-view image outputted by the third imaging unit 150 is acquired, and three-dimensional coordinates of the reference position of the semiconductor chip 310 are recognized based on the image coordinates of the chip reference mark 311 and the like reflected.

In step S1206, the mounting control part 214 raises the bonding tool 120 to a position at which the held semiconductor chip 310 retracts from the field of view of the top-view imaging units, and moves the head part 110 such that the bonding tool 120 is directly above the die pad 320 on which the semiconductor chip 310 is to be placed. In subsequent step S1207, the height of the head part 110 is adjusted such that the focal plane 110a of the top-view imaging units coincides with the frame surface 330a of the lead frame 330.

After such arrangement adjustment is completed, in step S1208, the mounting control part 214 causes the first imaging unit 130 and the second imaging unit 140 to capture an image of the unit area 322 including the target die pad 320 and the pad reference mark 321 on the planned placement surface. Then, in step S1209, a first top-view image outputted by the first imaging unit 130 and a second top-view image outputted by the second imaging unit 140 are acquired, and three-dimensional coordinates of the target position are calculated based on the image coordinates of the pad reference mark 321 reflected, the calibration value, etc.

After the target position is confirmed, proceeding to step S1210, the head part 110 and the bonding tool 120 are moved such that the reference position of the semiconductor chip 310 matches the target position, and the semiconductor chip 310 is placed on the die pad 320. Thereafter, the semiconductor chip 310 is pressed/heated to complete the bonding. After bonding is completed, the bonding tool 120 is raised, and the process returns to the main flow.

FIG. 18 is a sub-flowchart illustrating the procedure of the parallel adjustment step. In the parallel adjustment step, the processing described with reference to FIG. 13 and FIG. 14 is mainly executed.

In step S1501, the detection part 215 acquires three-dimensional coordinates of the pad reference marks of three or more points calculated in the mounting control step. In subsequent step S1502, an inclination of the frame surface 330a with respect to the reference plane is detected based on the acquired three-dimensional coordinates. In step S1503, the drive control part 212 drives the stage drive motor 191 to configure the inclination detected by the detection part 215 to be zero, particularly in the present embodiment, to configure the frame surface 330a to be horizontal. At this time, in the case where the height of the frame surface 330a deviates from the height of the index surface 173a, height adjustment may be performed together to configure the height to be the same. After adjustment of the frame surface 330a is completed, the process returns to the main flow.

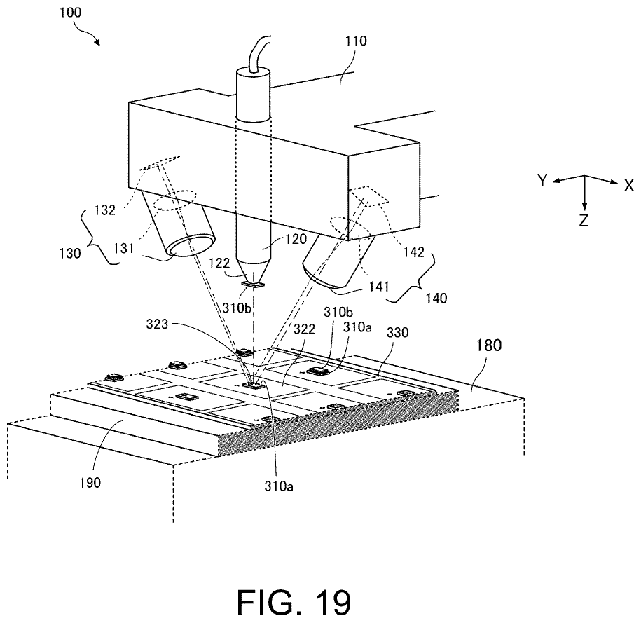

In the above description, the embodiment of bonding the semiconductor chip 310 to the frame surface 330a of the lead frame 330 has been described. However, in an embodiment of stacking and mounting a semiconductor chip to another semiconductor chip already mounted on a substrate surface, the above parallel adjustment may also be implemented. FIG. 19 is a partial perspective view of the bonding apparatus 100 for illustrating a first application example according to this embodiment. The bonding apparatus 100 according to the first application example has the same hardware configuration as the bonding apparatus 100 described above, but differs in terms of performing mounting control to stack and mount semiconductor chips. FIG. 19 corresponds to FIG. 9, and elements the same as the already described elements will be labeled with the same reference signs and descriptions thereof will be omitted, unless specifically mentioned.

The processing up to mounting a first semiconductor chip 310a, which serves as a first layer, on each unit area 322 of the lead frame 330 is similar to the processing up to mounting the semiconductor chip 310 on each unit area 322 in the description above. FIG. 19 illustrates mounting a second semiconductor chip 310b, which serves as a second layer, overlapping the first semiconductor chip 310a. Specifically, the figure shows a state in which the collet 122 adsorbs the second semiconductor chip 310b, which is about to be mounted, and the top-view imaging units capture an image of the upper surface of the already mounted first semiconductor chip 310a, which is a placement surface on which the second semiconductor chip 310b is placed.

A stacking reference mark 323 indicating the reference position is provided on the upper surface of the first semiconductor chip 310a, and the stacking reference mark 323 is also reflected in the first top-view image and the second top-view image. The mounting control part 214 calculates three-dimensional coordinates (Xⱼ, Yⱼ, Zⱼ) of the stacking reference mark 323 from the images. Herein, if the three-dimensional coordinates of two or more other stacking reference marks 323 have already been calculated, the detection part 215 can calculate an inclination of the work plane including the upper surface of each first semiconductor chip 310a with respect to the reference plane. If the work plane is inclined beyond the permissible range with respect to the reference plane, the drive control part 212 drives the stage drive motor 191 to eliminate the inclination. After the inclination is eliminated, or if no inclination beyond the permissible range is detected, the mounting control part 214 lowers the bonding tool 120 to bond the second semiconductor chip 310b to the upper surface of the first semiconductor chip 310a.

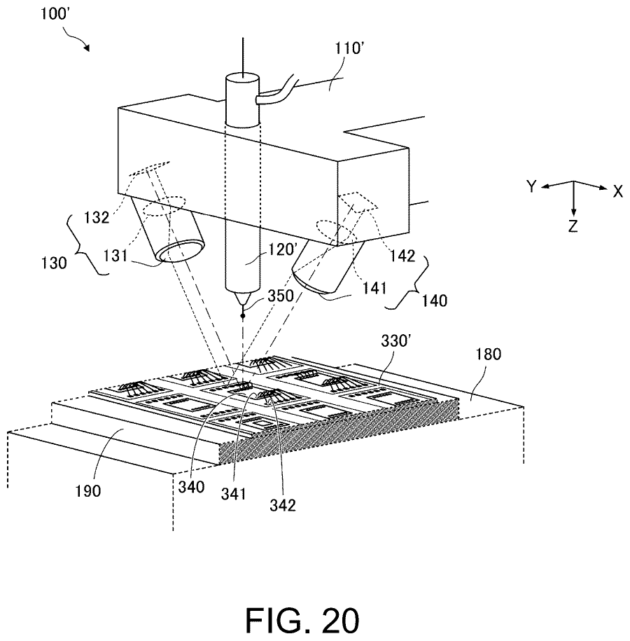

The above parallel adjustment may also be implemented in a wire bonder. FIG. 20 is a partial perspective view of a bonding apparatus 100′ serving as a wire bonder for illustrating a second application example according to this embodiment. FIG. 20 corresponds to FIG. 9, and elements the same as the already described elements will be labeled with the same reference signs and descriptions thereof will be omitted, unless specifically mentioned.

The bonding apparatus 100′ is a bonding apparatus that connects a pad electrode 341 of a semiconductor chip 340 with a lead electrode 342 of a lead frame 330′ by a wire 350, which is a bonding wire. The pad electrode 341 and the lead electrode 342 are targets for measuring three-dimensional coordinates and feeding the wire 350.

A head part 110′ supports a bonding tool 120′, a first imaging unit 130, and a second imaging unit 140. The bonding tool 120′ functions to feed the wire 350, which is, for example, a gold wire, and includes a wire clamp, a transducer, and a capillary. At the time of first bonding to the pad electrode 341, as shown in the figure, the wire 350 is extended from the tip, and a free air ball (FAB) is formed at the tip of the wire 350 by a torch electrode (not shown).

The mounting control part 214 captures, by the top-view imaging units, images of the pad electrode 341 and the lead electrode 342 to be connected by the wire 350, and calculates respective three-dimensional coordinates. Herein, if the three-dimensional coordinates of two or more other lead electrodes 342 have already been calculated, the detection part 215 can calculate an inclination of the frame surface of the lead frame 330′ with respect to the reference plane. If the frame surface is inclined beyond the permissible range with respect to the reference plane, the drive control part 212 drives the stage drive motor 191 such that the inclination is eliminated. After the inclination is eliminated, or if no inclination beyond the permissible range is detected, the mounting control part 214 lowers the bonding tool 120′ to execute a wire connection processing.

Although the present embodiment with two modification examples have been described above, the embodiment is not limited to these bonding apparatuses. In the case of being a semiconductor apparatus in which a mounting tool performing a mounting work on at least one of a substrate placed on a stage and other mounting bodies already mounted on the substrate is supported at a head part together with top-view imaging units, and the head part displaces with respect to the stage to perform a mounting processing, it is possible to detect the inclination of the stage surface or the work plane with respect to the reference plane using height information of each of multiple spots calculated based on a first top-view image and a second top-view image. In the present embodiment, although it has been described that the stage is driven to eliminate the detected inclination to continue the mounting processing, the subsequent processing based on the detected inclination is not limited to the processing of driving the stage. For example, the mounting processing may also be stopped at the time point at which an inclination beyond the permissible range is detected.

### REFERENCE SIGNS LIST

100, 100′ . . . bonding apparatus, 110, 110′ . . . head part, 110a . . . focal plane, 111 . . . head drive motor, 120, 120′ . . . bonding tool, 121 . . . tool drive motor, 122 . . . collet, 123 . . . collet center, 124 . . . heater, 130 . . . first imaging unit, 131 . . . first optical system, 131a . . . object-side lens group, 131b . . . image-side lens group, 132 . . . first imaging element, 133 . . . aperture, 140 . . . second imaging unit, 141 . . . second optical system, 142 . . . second imaging element, 150 . . . third imaging unit, 150a . . . focal plane, 151 . . . third optical system, 152, . . . third imaging element, 170 . . . calibration unit, 171 . . . index drive motor, 172 . . . index plate, 173 . . . calibration index, 173a . . . index surface, 180 . . . base, 190 . . . stage, 190a . . . stage surface, 191 . . . stage drive motor, 210 . . . arithmetic processing part, 211 . . . image acquisition part, 212 . . . drive control part, 213 . . . calibration control part, 214 . . . mounting control part, 215 . . . detection part, 220 . . . storage part, 221 . . . calibration data, 230 . . . input/output device, 310 . . . semiconductor chip, 310a . . . first semiconductor chip, 310b . . . second semiconductor chip, 311 . . . chip reference mark, 320 . . . die pad, 321 . . . pad reference mark, 321a . . . first pad reference mark, 321b . . . second pad reference mark, 321c . . . third pad reference mark, 322 . . . unit area, 322a . . . first unit area, 322b . . . second unit area, 322c . . . third unit area, 323 . . . stacking reference mark, 330, 330′ . . . lead frame, 330a . . . frame surface, 340 . . . semiconductor chip, 341 . . . pad electrode, 342 . . . lead electrode, 350 . . . wire, 500 . . . chip feeding apparatus, 510 . . . pickup mechanism, 520 . . . inversion mechanism

1. A mounting apparatus comprising:
a stage on which a substrate to be mounted with a mounting body is placed;
a mounting tool performing a mounting work on at least one of the substrate placed on the stage and another mounting body already mounted on the substrate;
a first imaging unit and a second imaging unit each comprising an optical system and an imaging element disposed to satisfy a Scheimpflug condition such that a plane parallel to a reference plane becomes a focal plane, and serving to capture, in a top view, images of a work area in which the mounting work is performed;
a head part supporting the mounting tool, the first imaging unit, and the second imaging unit and being displaceable with respect to the stage; and
a detection part detecting an inclination of a stage surface of the stage or a work plane including the work area with respect to the reference plane using height information of each of a plurality of spots calculated based on a first top-view image and a second top-view image obtained by displacing the head part and causing the first imaging unit and the second imaging unit to respectively capture and output images of the plurality of spots of the stage surface or the work plane.

2. The mounting apparatus according to claim 1, comprising:
a drive control part driving the stage such that the stage surface or the work plane becomes parallel to the reference plane based on the inclination detected by the detection part.

3. The mounting apparatus according to claim 2, comprising:
a mounting control part mounting the mounting body to the work area by controlling a control target including the mounting tool, wherein
the detection part uses, as the height information, a height coordinate of a specific spot of the stage surface or the work plane calculated together when the mounting control part calculates in-plane coordinates of the specific spot based on the first top-view image and the second top-view image in a series of works of mounting the mounting body.

4. The mounting apparatus according to claim 3, wherein
the detection part detects the inclination by using the height coordinate calculated in a work in which the mounting control part confirms a placement position of the substrate with respect to the stage, and
the drive control part drives the stage such that the work plane becomes parallel to the reference plane before the mounting control part places the mounting body in the work area.

5. The mounting apparatus according to claim 3, wherein
the detection part detects the inclination by using the height coordinates of the work plane respectively calculated during mounting of three or more mounting bodies by the mounting control part, and
the drive control part drives the stage such that the work plane becomes parallel to the reference plane before placing the mounting body in the work area in a case of further mounting the mounting body.

6. The mounting apparatus according to claim 3, comprising:
a third imaging unit for capturing, in a bottom view, an image of the mounting body in a state held by the mounting tool, from a side opposite to the first imaging unit and the second imaging unit with respect to the stage surface; and
a calibration control part that calculates a calibration value for calibrating a difference between a coordinate value calculated based on the first top-view image and the second top-view image respectively outputted by the first imaging unit and the second imaging unit and a coordinate value calculated based on a bottom-view image outputted by the third imaging unit, based on the first top-view image and the second top-view image of a calibration index set in advance captured and outputted respectively by the first imaging unit and the second imaging unit and the bottom-view image of the calibration index captured and outputted by the third imaging unit, wherein
the mounting control part recognizes a reference position of the mounting body based on the bottom-view image obtained by adjusting a position of the mounting tool such that the work plane is at a same height as an index surface of the calibration index and causing the third imaging unit to capture and output an image of a mounting surface of the mounting body, recognizes a target position of the work area based on the calibration value and the first top-view image and the second top-view image obtained by adjusting positions of the first imaging unit and the second imaging unit such that the focal plane is at a same height as the work plane, which is at the same height as the index surface, and causing the first imaging unit and the second imaging unit to respectively capture images of the work area, and places and mounts the mounting body in the work area such that the reference position matches the target position.

7. A mounting method, which is a mounting method of a mounting body using a mounting apparatus, the mounting apparatus comprising:
a stage on which a substrate to be mounted with the mounting body is placed;
a mounting tool performing a mounting work on at least one of the substrate placed on the stage and another mounting body already mounted on the substrate;
a first imaging unit and a second imaging unit each comprising an optical system and an imaging element disposed to satisfy a Scheimpflug condition such that a plane parallel to a reference plane becomes a focal plane, and serving to capture, in a top view, images of a work area in which the mounting work is performed; and
a head part supporting the mounting tool, the first imaging unit, and the second imaging unit and being displaceable with respect to the stage,
the mounting method comprising:
an acquisition step of acquiring height information of each of a plurality of spots calculated based on a first top-view image and a second top-view image obtained by displacing the head part and causing the first imaging unit and the second imaging unit to respectively capture and output images of the plurality of spots of a stage surface of the stage or a work plane including the work area; and
a detection step of detecting an inclination of the stage surface or the work plane with respect to the reference plane using the height information.

8. A non-transitory computer-readable recording medium recording a mounting control program, which is a mounting control program controlling a mounting apparatus, the mounting apparatus comprising:
a stage on which a substrate to be mounted with a mounting body is placed;
a mounting tool performing a mounting work on at least one of the substrate placed on the stage and another mounting body already mounted on the substrate;
a first imaging unit and a second imaging unit each comprising an optical system and an imaging element disposed to satisfy a Scheimpflug condition such that a plane parallel to a reference plane becomes a focal plane, and serving to capture, in a top view, images of a work area in which the mounting work is performed; and
a head part supporting the mounting tool, the first imaging unit, and the second imaging unit and being displaceable with respect to the stage,
the mounting control program causing a computer to execute:
an acquisition step of acquiring height information of each of a plurality of spots calculated based on a first top-view image and a second top-view image obtained by displacing the head part and causing the first imaging unit and the second imaging unit to respectively capture and output images of the plurality of spots of a stage surface of the stage or a work plane including the work area; and
a detection step of detecting an inclination of the stage surface or the work plane with respect to the reference plane using the height information.
